(19) United States
(12) Patent Application Publication
(10) Pub. No.: US 2026/0248005 A1
(43) Pub. Date: Aug. 20, 2026

(54) SEMICONDUCTOR MODULE

(71) Applicant: FUJI ELECTRIC CO., LTD., Kanagawa (JP)

(72) Inventor: Mitsuhiro KAKEFU, Matsumoto-city (JP)

(21) Appl. No.: 19/433,074

(22) Filed: Dec. 26, 2025

(30) Foreign Application Priority Data
Feb. 18, 2025 (JP) 2025-023938

(51) Int. Cl. H10W 70/654; H10W 70/65; H10W 90/10

(52) U.S. Cl. CPC H10W 70/654; H10W 70/658; H10W 90/10

(57) ABSTRACT

Provided is a semiconductor module including: a first sense terminal portion and a first gate terminal portion arranged side by side in a first direction; a first transistor chip that constitutes a lower arm; a wiring substrate; a first wiring pattern that is electrically connected between the first transistor chip and an N terminal portion; a second wiring pattern that is electrically connected between the first transistor chip and the first wiring pattern; a first sense pattern that is electrically connected between the second wiring pattern and the first sense terminal portion, and that is separated from the second wiring pattern; and a first gate pattern that is electrically connected between a gate pad of the first transistor chip and the first gate terminal portion, wherein the first sense pattern and the first gate pattern are aligned in the first direction.

### BACKGROUND

### TECHNICAL FIELD

The present invention relates to a semiconductor module.

### RELATED ART

Conventionally, a power semiconductor module with a plurality of transistor chips mounted thereon is known (for example, refer to Patent document 1, 2).

Patent document 1: Japanese Patent No. 6421049

Patent document 2: Japanese Unexamined Patent Publication No. 2002-368192

### BRIEF DESCRIPTION OF THE DRAWINGS

FIG. 1 shows an example of a semiconductor module 100 according to one embodiment of the present invention.

FIG. 2 is an enlarged drawing in the vicinity of a first wiring pattern 31 and a second wiring pattern 32 of the semiconductor module 100 shown in FIG. 1.

FIG. 3 shows an example of the semiconductor module 200 in a comparative example.

FIG. 4 shows an example of a circuit configuration of the semiconductor module 100.

FIG. 5 shows a connection position of a point-to-point construction 27 extending from a sense terminal portion.

FIG. 6 shows a semiconductor module 400 in a modification example of the present invention.

FIG. 7 is an enlarged drawing in the vicinity of a second wiring pattern 32 and a third wiring pattern 33 of the semiconductor module 400 shown in FIG. 6.

FIG. 8 shows a semiconductor module 500 in a modification example of the present invention.

FIG. 9 shows a semiconductor module 600 in a modification example of the present invention.

FIG. 10 shows a semiconductor module 700 in a modification example of the present invention.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention. Note that, in the present specification and the drawings, a repeated description for an element having a substantially same function and configuration is omitted by providing the same reference numeral, and illustration of an element which is not directly associated with the present invention is omitted. In addition, for elements having substantially the same function and configuration in one drawing, a reference numeral may be given to an element as a representative, and for the rest of the elements, the reference numeral may not be given.

Herein, one side in a direction parallel to a depth direction of the switching device is referred to as “upper”, and another side is referred to as “lower”. One surface of two principal surfaces of a substrate, a layer or another member is referred to as an upper surface, and another surface is referred to as a lower surface. The 'upper' and 'lower' directions are not limited to a gravity direction or a direction at a time of mounting a semiconductor module.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. Note that a +Z axis direction and a -Z axis direction are directions opposite to each other. When the Z axis direction is described without describing the signs, it means that the direction is parallel to the +Z axis and the -Z axis. Herein, each orthogonal axis parallel to the upper surface and the lower surface of the switching device is the X axis and the Y axis. Also, an axis perpendicular to the upper surface and the lower surface of the switching device is the Z axis. In the present specification, the direction of the Z axis may be referred to as the depth direction. Also, herein, a direction parallel to the upper surface and the lower surface of the switching device, including the X axis and the Y axis, may be referred to as a horizontal direction.

In the present specification, a case where a term such as “same” or “equal” is mentioned may include a case where an error due to a variation in manufacturing or the like is included. The error is, for example, within 10%.

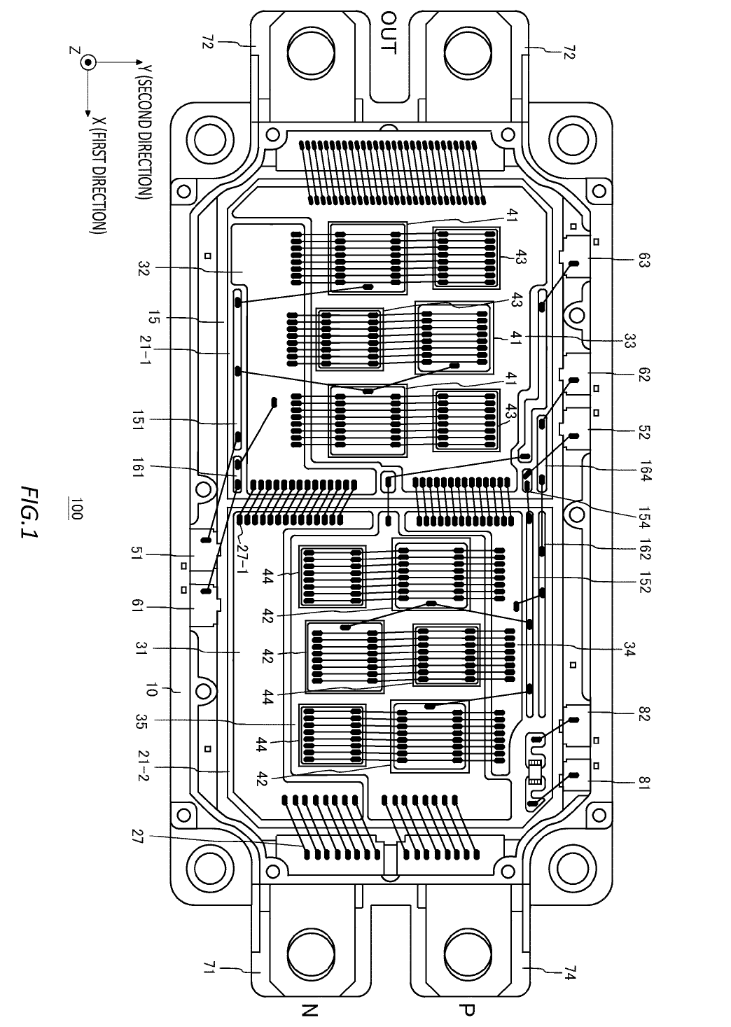

FIG. 1 shows an example of a semiconductor module 100 according to one embodiment of the present invention. The semiconductor module 100 may function as a power conversion apparatus such as an inverter or a converter. A rated current of the semiconductor module 100 may be 100A or more, as an example. The semiconductor module 100 has a switching device such as a transistor contained therein. The semiconductor module 100 of the present example includes a resin casing 10, a base plate 15, and a wiring substrate 21.

The resin casing 10 has a switching device contained therein. In the present example, the resin casing 10 contains a plurality of first transistor chips 41, a plurality of second transistor chips 42, a plurality of first diode chips 43, and a plurality of second diode chips 44.

As an example, the resin casing 10 is connected to the base plate 15 in which the wiring substrate 21 is arranged. In a corner portion of the resin casing 10, a through hole, such as a threaded hole for fixing the semiconductor module 100 outside may be provided. In the resin casing 10, a side wall may be provided to surround the switching device positioned inside.

In the resin casing 10, a plurality of main terminal portions are provided. In the present example, in the resin casing 10, an N terminal portion 71, an OUT terminal portion 72, and a P terminal portion 74 are provided. The plurality of main terminal portions are electrically connected to the switching device arranged on the wiring substrate 21. Each main terminal portion is formed of a conductive material. For example, each main terminal portion is a current path of a large current flowing in a power device such as an IGBT. The main terminal portion of the present example is plate-shaped.

A current is input from an external power supply and the like to the P terminal portion 74. The OUT terminal portion 72 is an example of an output terminal. The OUT terminal portion 72 is connected to a load outside a module, and outputs the current from the P terminal portion 74 to the load outside the module. A current flows from the OUT terminal portion 72 into the N terminal portion 71.

In the resin casing 10, a gate terminal portion is provided. In the resin casing 10 of the present example, a first gate terminal portion 51 and a second gate terminal portion 52 are provided. The first gate terminal portion 51 and the second gate terminal portion 52 may have a smaller area than that of the main terminal portion in a top view. The first gate terminal portion 51 and the second gate terminal portion 52 are electrically connected to a switching device that is arranged on the wiring substrate 21. By applying a gate voltage to a gate terminal portion, the gate voltage is applied to a gate pad of the switching device. Therefore, by controlling the gate voltage, the switching device can be controlled.

In the resin casing 10, a sense terminal portion is provided. In the resin casing 10 of the present example, a first sense terminal portion 61, a second sense terminal portion 62, and a third sense terminal portion 63 are provided. A sense terminal portion may measure a potential inside the semiconductor module 100. The sense terminal portion of the present example measures a potential of a wiring pattern described below. Based on the measured potential, a voltage applied to the switching device and a current flowing in the switching device may be calculated. Each terminal portion may include an end portion exposed to the outside of the module (for example, a pin), and an internal block (for example, formed of copper and the like) that is connected to the pin inside the module.

In the resin casing 10, a temperature sense terminal portion may be provided. In the resin casing 10 of the present example, a temperature sense terminal portion 81, and a temperature sense terminal portion 82 are provided. A diode, a thermistor, or the like for temperature sensing may be connected to the temperature sense terminal portion 81 and the temperature sense terminal portion 82. By measuring a forward voltage of the diode, the thermistor, or the like for temperature sensing using the temperature sense terminal portion 81 and the temperature sense terminal portion 82, the temperature inside the semiconductor module 100 may be measured.

In the present example, the resin casing 10 and the base plate 15 are molded with resin such as thermosetting resin with which they can be formed through injection molding, or ultraviolet curing resin with which they can be formed through UV molding. The resin may include, for example, one or more polymer materials selected from polyphenylene sulfide (PPS) resin, polybutylene terephthalate (PBT) resin, polyamide (PA) resin, acrylonitrile butadiene styrene (ABS) resin, acrylic resin, and the like.

On the base plate 15, one or more wiring substrates 21 are arranged. In the present example, on the base plate 15, a wiring substrate 21-1 and a wiring substrate 21-2 are arranged side by side in an X axis direction. In the wiring substrate 21, at least one switching device is arranged. In the present example, three first transistor chips 41 and three first diode chips 43 are arranged on the wiring substrate 21-1, and three second transistor chips 42 and three second diode chips 44 are arranged on the wiring substrate 21-2. Note that the number of elements is not limited thereto.

In the present example, the first transistor chip 41 and the second transistor chip 42 are IGBTs, and the first diode chip 43 and the second diode chip 44 are FWDs (Free Wheel Diode). Each of the first transistor chip 41 and the second transistor chip 42 may be a MOSFET. On the wiring substrate 21, an RC (Reverse Conducting) - IGBT obtained by combining the IGBT, the FWD, and the like may be arranged. On the front surface of each of the first transistor chip 41 and the second transistor chip 42, a main electrode and a gate pad are provided. The main electrode is an emitter electrode, by way of example. Also, on the back surface of each of the first transistor chip 41 and the second transistor chip 42, a back surface electrode is provided. The back surface electrode is a collector electrode, by way of example. When the first transistor chip 41 and the second transistor chip 42 are MOSFETs, the emitter electrode may be interpreted as a source electrode, and the collector electrode may be interpreted as a drain electrode, respectively. On the front surface of each of the first diode chip 43 and the second diode chip 44, an anode electrode is provided. On the back surface of each of the first diode chip 43 and the second diode chip 44, a cathode electrode is provided. The second transistor chip 42 may configure an upper arm of the semiconductor module 100. The first transistor chip 41 may configure a lower arm of the semiconductor module 100.

On the upper surface of the wiring substrate 21, a wiring pattern is arranged. The wiring pattern is a conductive pattern provided on the wiring substrate 21. The wiring pattern may be configured, by directly joining or joining via a brazing layer, a copper plate, or an aluminum plate, or alternatively a plate plated with these materials, to a wiring substrate 21 such as an aluminum oxide ceramics, a silicon nitride ceramics, and an aluminum nitride ceramics. The wiring substrate 21 may be obtained by adding zirconium oxide, yttrium oxide, or the like to the ceramics. Also, the wiring pattern may be an alloy including at least any one of copper or aluminum. Note that the wiring substrate 21 and the wiring pattern may also be obtained by laminating an insulation sheet on a conductive member such as a copper plate or an aluminum plate. That is, the wiring substrate 21 and the wiring pattern may be a plate member obtained by integrating a conductive member and an insulating member.

The wiring substrate 21 of the present example is provided with a first wiring pattern 31, a second wiring pattern 32, a third wiring pattern 33, a fourth wiring pattern 34, and a fifth wiring pattern 35. The first wiring pattern 31 is electrically connected between the first transistor chip 41 and the N terminal portion 71. Herein, being electrically connected may include being indirectly connected via another pattern and the like, in addition to being directly coupled to each configuration. The first wiring pattern 31 of the present example is indirectly connected to the first transistor chip 41 via the second wiring pattern 32. The first wiring pattern 31 of the present example is connected to the N terminal portion 71 using a point-to-point construction 27. Herein, connecting configuration A and configuration B to the point-to-point construction 27 may mean that the configuration A and the configuration B are directly coupled to the point-to-point construction 27. In other words, it may mean that another pattern that relays the point-to-point construction 27 between the configuration A and the configuration B does not exist. The point-to-point construction 27 may be a wire. In FIG. 1, a place at which the point-to-point construction 27 and each wiring pattern and the like are connected is shown with black-lacquer. The point-to-point construction 27 and each wiring pattern and the like may be connected by wire bonding. The first wiring pattern 31 of the present example is provided on the wiring substrate 21-2.

The second wiring pattern 32 is electrically connected between the first transistor chip 41 and the first wiring pattern 31. The second wiring pattern 32 of the present example is connected to the first wiring pattern 31 using the point-to-point construction 27. The second wiring pattern 32 of the present example is connected to the first transistor chip 41 using the point-to-point construction 27. The second wiring pattern 32 may be connected to an emitter electrode of each first transistor chip 41, and an anode electrode of each first diode chip 43 using the point-to-point construction 27. The second wiring pattern 32 of the present example is provided on the wiring substrate 21-1.

The third wiring pattern 33 is electrically connected between the second transistor chip 42 and the OUT terminal portion 72. The third wiring pattern 33 of the present example is connected to the OUT terminal portion 72 using a point-to-point construction 27. The third wiring pattern 33 of the present example is indirectly connected to the fourth wiring pattern 34 via the second transistor chip 42. A plurality of first transistor chips 41 and a plurality of first diode chips 43 are provided on the upper surface of the third wiring pattern 33 of the present example. A collector electrode of each first transistor chip 41 and a cathode electrode of each first diode chip 43 are connected to the third wiring pattern 33. The third wiring pattern 33 of the present example is provided on the wiring substrate 21-1.

The fourth wiring pattern 34 is electrically connected between the second transistor chip 42 and the third wiring pattern 33. The fourth wiring pattern 34 of the present example is connected to the third wiring pattern 33 using the point-to-point construction 27. The fourth wiring pattern 34 of the present example is connected to the second transistor chip 42 using the point-to-point construction 27. The fourth wiring pattern 34 may be connected to an emitter electrode of each second transistor chip 42, and an anode electrode of each second diode chip 44 using the point-to-point construction 27. The fourth wiring pattern 34 of the present example is provided on the wiring substrate 21-2.

The fifth wiring pattern 35 is electrically connected between the second transistor chip 42 and the P terminal portion 74. The fifth wiring pattern 35 of the present example is connected to the P terminal portion 74 using the point-to-point construction 27. A plurality of second transistor chips 42 and a plurality of second diode chips 44 are provided on the upper surface of the fifth wiring pattern 35 of the present example. A collector electrode of each second transistor chip 42 and a cathode electrode of each second diode chip 44 are connected to the fifth wiring pattern 35. The fifth wiring pattern 35 of the present example is provided on the wiring substrate 21-2. Note that each wiring pattern and the like may be connected by a plurality of point-to-point constructions 27.

A current from the P terminal portion 74 flows to the OUT terminal portion 72 via the fifth wiring pattern 35, the second transistor chip 42, the fourth wiring pattern 34, and the third wiring pattern 33. Also, a current from the OUT terminal portion 72 flows to the N terminal portion 71 via the third wiring pattern 33, the first transistor chip 41, the second wiring pattern 32, and the first wiring pattern 31. Each of the first wiring pattern 31 and the second wiring pattern 32 may be a current path between a switching device that constitutes the lower arm and the N terminal portion 71. Each of the third wiring pattern 33 and the fourth wiring pattern 34 may be a current path between a switching device that constitutes the upper arm and the OUT terminal portion 72.

A first gate pattern 151 and a second gate pattern 152 are provided on the wiring substrate 21 of the present example. The first gate pattern 151 is electrically connected between a gate pad of the first transistor chip 41 and the first gate terminal portion 51. The first gate pattern 151 of the present example is connected to the first gate terminal portion 51 using the point-to-point construction 27. The first gate pattern 151 of the present example is connected to a gate pad of each first transistor chip 41 using the point-to-point construction 27. The first gate pattern 151 relays between the first gate terminal portion 51 and the gate pad of each first transistor chip 41. The first gate pattern 151 of the present example is provided on the wiring substrate 21-1.

The second gate pattern 152 is electrically connected between a gate pad of the second transistor chip 42 and the second gate terminal portion 52. The second gate pattern 152 of the present example is connected to the fourth gate pattern 154 using the point-to-point construction 27. The fourth gate pattern 154 is connected to the second gate terminal portion 52 using the point-to-point construction 27. That is, the second gate pattern 152 and the second gate terminal portion 52 are indirectly connected via the fourth gate pattern 154. Also, the second gate pattern 152 of the present example is connected to a gate pad of each second transistor chip 42 using the point-to-point construction 27. The second gate pattern 152 and the fourth gate pattern 154 relay between the second gate terminal portion 52 and a gate pad of each second transistor chip 42. The second gate pattern 152 of the present example is provided on the wiring substrate 21-2, and the fourth gate pattern 154 is provided on the wiring substrate 21-1.

The wiring substrate 21 of the present example is provided with a first sense pattern 161, a second sense pattern 162, and a fourth sense pattern 164. The first sense pattern 161 is electrically connected between the second wiring pattern 32 and the first sense terminal portion 61. The first sense pattern 161 of the present example is connected to the first sense terminal portion 61 using the point-to-point construction 27. The first sense pattern 161 of the present example is connected to the second wiring pattern 32 using the point-to-point construction 27. The first sense pattern 161 relays between the first sense terminal portion 61 and the second wiring pattern 32. The first sense pattern 161 of the present example is provided on the wiring substrate 21-1.

The second sense pattern 162 may be electrically connected between the fourth wiring pattern 34 and the second sense terminal portion 62. The second sense pattern 162 of the present example is connected to the fourth sense pattern 164 using the point-to-point construction 27. The fourth sense pattern 164 is connected to the second sense terminal portion 62 using the point-to-point construction 27. That is, the second sense pattern 162 and the second sense terminal portion 62 are indirectly connected via the fourth sense pattern 164. Also, the second sense pattern 162 of the present example is connected to the fourth wiring pattern 34 using the point-to-point construction 27. The second sense pattern 162 and the fourth sense pattern 164 relay between the second sense terminal portion 62 and the fourth wiring pattern 34. The second sense pattern 162 of the present example is provided on the wiring substrate 21-2, and the fourth sense pattern 164 is provided on the wiring substrate 21-1.

The first sense pattern 161 may be electrically connected between the first transistor chip 41 and the first sense terminal portion 61. In the present example, the first transistor chip 41 and the first sense pattern 161 are indirectly connected via the second wiring pattern 32. The second sense pattern 162 may be electrically connected between the second transistor chip 42 and the second sense terminal portion 62. In the present example, the second transistor chip 42 and the second sense pattern 162 are electrically connected via the fourth wiring pattern 34. Note that a resin may be provided inside the resin casing 10, but it is omitted in FIG. 1.

The first sense pattern 161 of the present example is separated from the second wiring pattern 32. In this way, since the point-to-point construction 27 can be connected to any position on the second wiring pattern 32, a potential on the second wiring pattern 32 can be accurately measured, and a loss of the switching device, for example, can be accurately calculated, as described below. Similarly, the second sense pattern 162 may be separated from the fourth wiring pattern 34. Also, the fourth sense pattern 164 may be separated from the third wiring pattern 33 in a similar manner. Also, all of the patterns described above may be separated from each other.

A direction in which the first sense terminal portion 61 and the first gate terminal portion 51 are arranged side by side is a first direction. The first direction of the present example is the X axis direction. The first direction may be parallel to a side wall of the resin casing 10. Also, in a top view, a direction perpendicular to the first direction is a second direction. The second direction of the present example is a Y axis direction. The top view may mean seeing from a direction perpendicular to the upper surface of the switching device, the wiring substrate 21 or the wiring pattern.

The first sense pattern 161 and the first gate pattern 151 of the present example are aligned in the first direction. In other words, the first sense pattern 161 and the first gate pattern 151 of the present example at least partially overlap in the first direction. In this way, the length of each of the first wiring pattern 31 and the second wiring pattern 32 in the second direction can be increased, and the number of the point-to-point construction 27 connecting the first wiring pattern 31 and the second wiring pattern 32 can be increased. In this way, the amount of current carried in one point-to-point construction 27 (a current duty) can be reduced, and the temperature rise in the point-to-point construction 27 can be suppressed. Therefore, the reliability of the semiconductor module 100 is improved. 80% or more of the first sense pattern 161 in the second direction and 80% or more of the first gate pattern 151 in the second direction may overlap in the first direction. The above ratio may be 90% or more, or may be 100% or more.

The first wiring pattern 31 and the second wiring pattern 32 may be aligned in the first direction. Between the first wiring pattern 31 and the second wiring pattern 32 in the first direction, a pattern other than the first sense pattern 161 and the first gate pattern 151 (a third sense pattern 163 and a third gate pattern 153, and the like, which will be described below) may not be provided. On the wiring substrate 21-2, between the first wiring pattern 31 and the second wiring pattern 32 in the first direction, another pattern (a third sense pattern 163 and a third gate pattern 153, and the like, which will be described below) may not be provided.

Each of the first sense pattern 161 and the first gate pattern 151 may be aligned with the second wiring pattern 32 in the second direction. The entire first sense pattern 161 in the first direction may be aligned with the second wiring pattern 32 in the second direction. The entire first gate pattern 151 in the first direction may be aligned with the second wiring pattern 32 in the second direction.

The first sense terminal portion 61 and the first gate terminal portion 51 may be arranged at a predetermined position determined by a product standard. Each of the first sense terminal portion 61 and the first gate terminal portion 51 of the present example is aligned with the first wiring pattern 31 in the second direction. The entire first sense terminal portion 61 in the first direction may be aligned with the first wiring pattern 31 in the second direction. The entire first gate terminal portion 51 in the first direction may be aligned with the first wiring pattern 31 in the second direction.

Each of the first sense pattern 161 and the first gate pattern 151 may have a longitudinal portion extending in the first direction. Each longitudinal portion may be aligned in the first direction. In this way, while the area on the first sense pattern 161 and the first gate pattern 151, which is occupied by the point-to-point construction 27 connecting therebetween, is secured, the number of the point-to-point construction 27 connecting the first wiring pattern 31 and the second wiring pattern 32 can be increased.

The first sense pattern 161 and the first gate pattern 151 may not be aligned with each other in the second direction. In other words, the first sense pattern 161 and the first gate pattern 151 may not have a portion overlapping each other in the second direction. In this way, the length of the second wiring pattern 32 in the second direction can be increased, and the number of the point-to-point construction 27 connecting the first wiring pattern 31 and the second wiring pattern 32 can be increased.

Each of the first sense pattern 161 and the first gate pattern 151 may be aligned with the first wiring pattern 31 in the first direction. The entire first sense pattern 161 and the first gate pattern 151 in the second direction may be aligned with the first wiring pattern 31 in the first direction. In this way, the length of the first wiring pattern 31 in the second direction can be increased.

Neither the first sense pattern 161 nor the first gate pattern 151 may be aligned with the first wiring pattern 31 in the second direction. In other words, the first sense pattern 161 and the first gate pattern 151 may not have a portion overlapping with the first wiring pattern 31 in the second direction. In this way, the length of the first wiring pattern 31 in the second direction can be increased.

The point-to-point construction 27 connected to the second wiring pattern 32 may be at least partially connected to a position in the first wiring pattern 31, the position overlapping both the first sense pattern 161 and the first gate pattern 151 in the first direction. In the present example, the point-to-point construction 27-1 that is positioned at a position that is the closest to the negative side in the second direction among the point-to-point constructions 27 connecting the first wiring pattern 31 and the second wiring pattern 32 is connected to the position. The position is a portion that can be connected by the arrangement of the first sense pattern 161 and the first gate pattern 151 described above, and by connecting the point-to-point construction 27 to the position, the number of the point-to-point constructions 27 connecting the first wiring pattern 31 and the second wiring pattern 32 can be increased. The point-to-point construction 27-1 connected to the position may be extended to have a gradient relative to the first direction and the second direction. The gradient may be a gradient in a top view. In this way, the number of the point-to-point constructions 27 connecting the first wiring pattern 31 and the second wiring pattern 32 can be increased. All of the point-to-point constructions 27 connecting the first wiring pattern 31 and the second wiring pattern 32 may be extended to have a gradient relative to the first direction and the second direction.

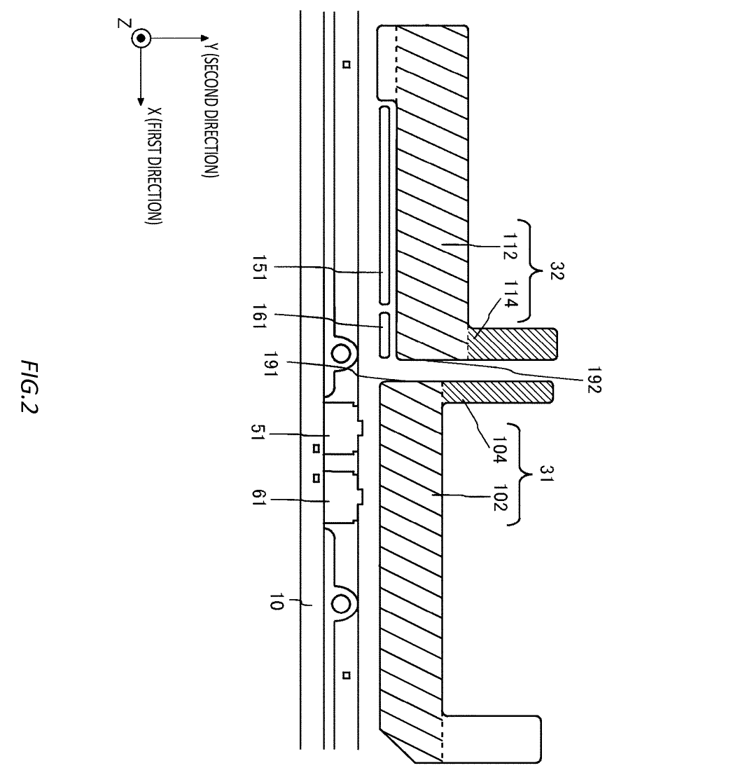

FIG. 2 is an enlarged drawing in the vicinity of a first wiring pattern 31 and a second wiring pattern 32 of the semiconductor module 100 shown in FIG. 1. In FIG. 2, the first wiring pattern 31, the second wiring pattern 32, the first gate terminal portion 51, the first sense terminal portion 61, the first gate pattern 151, and the first sense pattern 161 are shown, and the illustrations of another configuration such as the switching device or the point-to-point construction 27 are omitted.

The first wiring pattern 31 may have a first wide portion 102 and a first narrow portion 104. The first wide portion 102 may include a portion having the greatest length of the first wiring pattern 31 in the first direction. The first wide portion 102 may be a portion having a length of half or more of the longest length of the first wiring pattern 31 in the first direction. The first narrow portion 104 is a portion having a length smaller than that of the first wide portion 102 in the first direction. If there are a plurality of portions, each of which is equivalent to the portion, the first narrow portion 104 may be a portion that is the closest to the second wiring pattern 32. The length of the first narrow portion 104 in the first direction may be half or less, or may be one quarter or less of the length of the first wide portion 102 in the first direction. The first wide portion 102 and the first narrow portion 104 may not have a portion overlapping with each other in the first direction. In FIG. 2, the first wide portion 102 is roughly hatched, and the first narrow portion 104 is finely hatched.

The first wide portion 102 may be aligned with each of the first sense pattern 161 and the first gate pattern 151 in the first direction. A current flowing from the second wiring pattern 32 to the first wiring pattern 31 is concentrated at a position closer to the first wide portion 102 than the first narrow portion 104 in the first wiring pattern 31. In this way, the length of the first wide portion 102, in which the current is concentrated, in the second direction can be increased.

A plurality of point-to-point constructions 27 may be connected to the first wide portion 102 (see FIG. 1). Most of the current flowing from the second wiring pattern 32 to the first wiring pattern 31 flows in the point-to-point construction 27 connected to the first wide portion 102. Therefore, it is desirable that the plurality of point-to-point constructions 27 are connected to the first wide portion 102 to reduce the current duty per one piece of the point-to-point construction 27. A connecting portion of the point-to-point construction 27 that is connected to the first wide portion 102 may be aligned in the second direction. The quantity of the point-to-point constructions 27 connected to the first wide portion 102 may be six or more. In the first wide portion 102, the connecting portions of six or more point-to-point constructions 27 may be aligned in a single line along the second direction.

The second wiring pattern 32 may have a second wide portion 112 and a second narrow portion 114. The second wide portion 112 may include a portion having the greatest length of the second wiring pattern 32 in the first direction. The second wide portion 112 may be a portion having a length of half or more of the longest length of the second wiring pattern 32 in the first direction. The second narrow portion 114 is a portion having a width smaller than that of the second wide portion 112 in the first direction. If there are a plurality of portions, each of which is equivalent to the portion, the second narrow portion 114 may be a portion that is the closest to the first wiring pattern 31. The length of the second narrow portion 114 in the first direction may be half or less, or may be one quarter or less of the length of the second wide portion 112 in the first direction. The second wide portion 112 and the second narrow portion 114 may not have a portion overlapping with each other in the first direction. In FIG. 2, the second wide portion 112 is roughly hatched, and the second narrow portion 114 is finely hatched.

The current flowing in the second wiring pattern 32 is concentrated in the second wide portion 112. A plurality of point-to-point constructions 27 may be connected to the second wide portion 112 (see FIG. 1). In this way, a current duty per one piece of point-to-point construction 27 can be reduced. A connecting portion of the point-to-point construction 27 that is connected to the second wide portion 112 may be aligned in the second direction. The quantity of the point-to-point constructions 27 connected to the second wide portion 112 may be six or more. In the second wide portion 112, the connecting portions of six or more point-to-point constructions 27 may be aligned in a single line along the second direction.

An end side facing the second wiring pattern 32 in the first wiring pattern 31 is referred to as a first end side 191. An end side facing the first wiring pattern 31 in the second wiring pattern 32 is referred to as a second end side 192. The first end side 191 may extend, in the second direction, closer to a side of the first gate terminal portion 51 than the second end side 192. In FIG. 2, the first end side 191 extends closer to the negative side in the second direction than the second end side 192. The first end side 191 may face, in the first direction, the first gate pattern 151 and the first sense pattern 161. In this way, the length of the first wiring pattern 31 in the second direction can be increased.

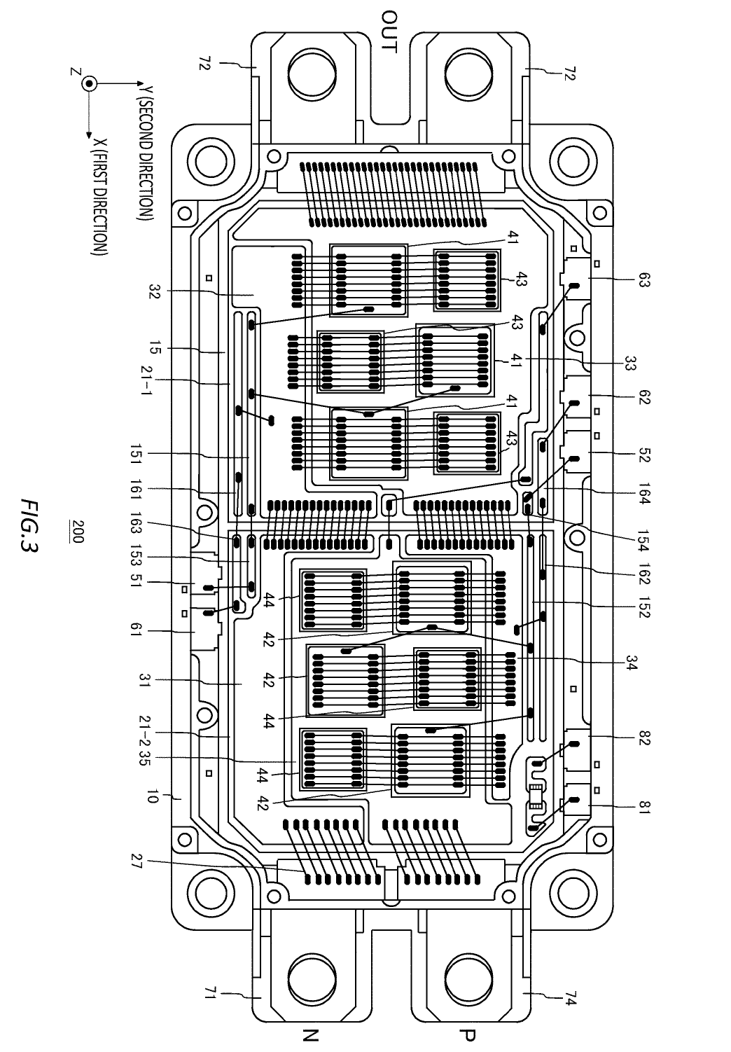

FIG. 3 shows an example of the semiconductor module 200 in a comparative example. The semiconductor module 200 of the comparative example has an arrangement of the first gate pattern 151 and the first sense pattern 161 that is different from that of the semiconductor module 100. Also, the semiconductor module 200 of the comparative example has a third gate pattern 153 and a third sense pattern 163.

In the comparative example, the first gate pattern 151 and the first sense pattern 161 are not aligned in the first direction. In the comparative example, the first gate pattern 151 and the first sense pattern 161 are aligned in the second direction. Therefore, the length of the second direction of the second wide portion 112 (see FIG. 2) of the second wiring pattern 32 is less than that of the semiconductor module 100. Therefore, the number of the point-to-point constructions 27 connected to the second wide portion 112 is also reduced.

In the comparative example, the first gate pattern 151 is connected to the third gate pattern 153 using the point-to-point construction 27. The third gate pattern 153 is connected to the first gate terminal portion 51 using the point-to-point construction 27. Also, in the comparative example, the first sense pattern 161 is connected to the third sense pattern 163 using the point-to-point construction 27. The third sense pattern 163 is connected to the first sense terminal portion 61 using the point-to-point construction 27. The third gate pattern 153 and the third sense pattern 163 are provided on the wiring substrate 21-2. By providing the third gate pattern 153 and the third sense pattern 163, the length of the first wide portion 102 (see FIG. 2) of the first wiring pattern 31 in the second direction is less than that of the semiconductor module 100. Therefore, the number of the point-to-point constructions 27 connected to the first wide portion 102 is six in the semiconductor module 100, there are three in the comparative example. The first wide portion 102 and the second wide portion 112 are places at which the current is concentrated, in the semiconductor module 200 of the comparative example, the current is concentrated in the three point-to-point constructions 27. That is, the current duty per one point-to-point construction 27 increases. As a result, the temperature of the point-to-point construction 27 may rise, to reduce the reliability of the module. In the semiconductor module 100, the current flows in the six point-to-point constructions 27, and therefore the current duty per one point-to-point construction 27 can be reduced.

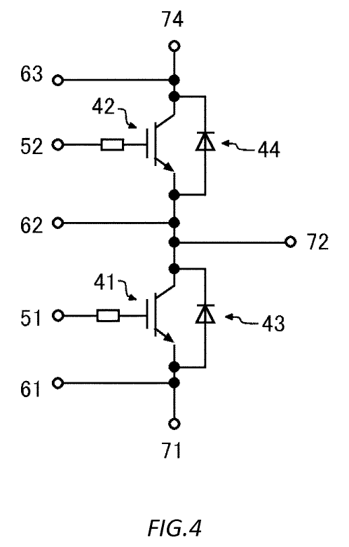

FIG. 4 shows an example of a circuit configuration of the semiconductor module 100. In the present example, each of the first transistor chip 41, the second transistor chip 42, the first diode chip 43, and the second diode chip 44 are shown as only one, but the plurality of chips (elements) may be connected in parallel.

The first transistor chip 41 and the second transistor chip 42 are electrically connected in series between the P terminal portion 74 and the N terminal portion 71. In the present example, the emitter electrode of the first transistor chip 41 and the anode electrode of the first diode chip 43 are connected to the N terminal portion 71. Also, the collector electrode of the second transistor chip 42 and the cathode electrode of the second diode chip 44 are connected to the P terminal portion 74.

The connection nodes of the first transistor chip 41 and the second transistor chip 42 are electrically connected to the OUT terminal portion 72. In the present example, each connection node of an upper arm configured by the second transistor chip 42 and the second diode chip 44, and a lower arm configured by the first transistor chip 41 and the first diode chip 43 is connected to the OUT terminal portion 72.

The first gate terminal portion 51 is connected to the gate pad of the first transistor chip 41. The second gate terminal portion 52 is connected to the gate pad of the second transistor chip 42. The first sense terminal portion 61 is connected between the first transistor chip 41 and the N terminal portion 71. The second sense terminal portion 62 is connected between the first transistor chip 41 and the second transistor chip 42. The third sense terminal portion 63 is connected between the second transistor chip 42 and the P terminal portion 74.

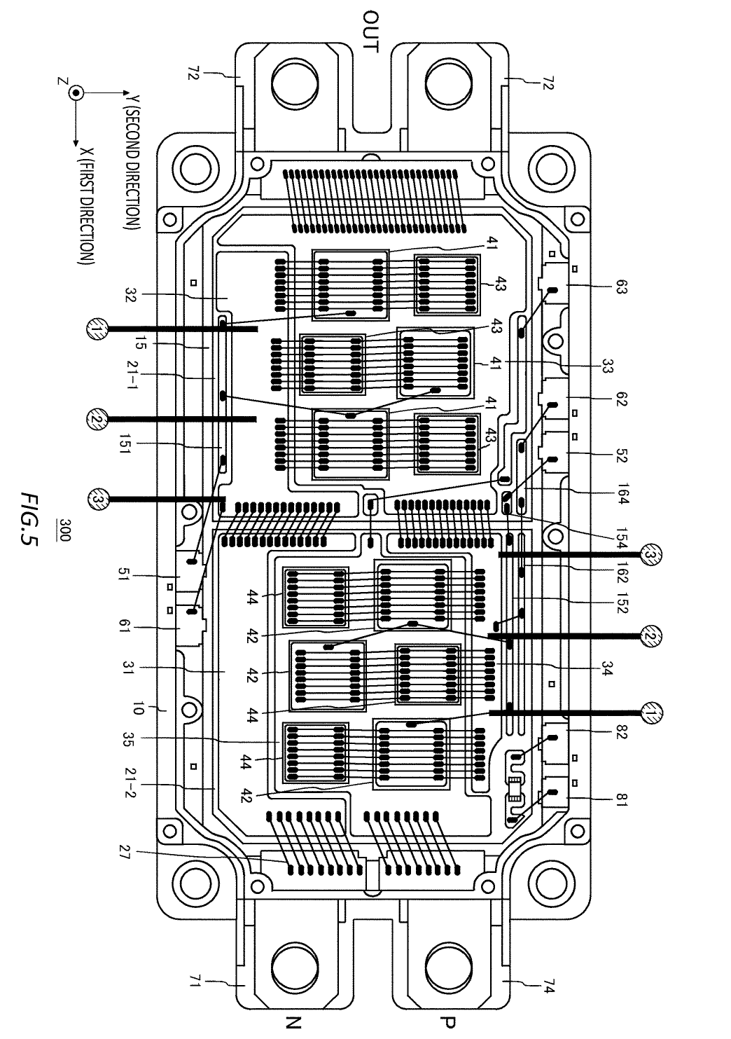

FIG. 5 shows a connection position of a point-to-point construction 27 extending from a sense terminal portion. In the semiconductor module 300 shown in FIG. 5, the position 1 to the position 3 are shown in each of the second wiring pattern 32 on the lower arm side and the fourth wiring pattern 34 on the upper arm side. Each of the position 1 to the position 3 expresses a connection position of the point-to-point construction 27 extending from the sense terminal portion. The position 1 and the position 2 are positioned near the center in the second direction of the wiring pattern. The position 3 is positioned near the end portion in the second direction of the wiring pattern. The position 3 of the second wiring pattern 32 is positioned in a place in which the first sense pattern 161 has been positioned, when the first sense pattern 161 and the second wiring pattern 32 are integrated without being separated.

For each of the position 1 to the position 3, a turn-on loss of the switching device is measured. As an example, the turn-on loss for the position 1 of the second wiring pattern 32 is 66.0 mJ, and the turn-on loss for the position 2 of the second wiring pattern 32 is 76. On the other hand, the turn-on loss for the position 3 of the second wiring pattern 32 is 217.6 mJ. The potential varies depending on the position on the wiring pattern, the value of loss calculated also varies. The loss can be correctly calculated using the potential closer to the center than that of the end portion on the wiring pattern. That is, for the position 3, the loss is calculated to be large since the potential varies on the wiring pattern. Therefore, it is desirable that the connection position of the point-to-point construction 27 that is extending from the sense terminal portion is near the center of the wiring pattern shown in the position 1 or the position 2. By providing the first sense pattern 161 that is separated from the second wiring pattern 32 and relaying the point-to-point construction 27 from the first sense terminal portion 61, the point-to-point construction 27 can be connected to a position near the center on the second wiring pattern 32. Therefore, in the semiconductor module 100 shown in FIG. 1, the loss can be calculated correctly. A similar tendency was observed in the position 1 to the position 3 of the fourth wiring pattern 34 on the upper arm side.

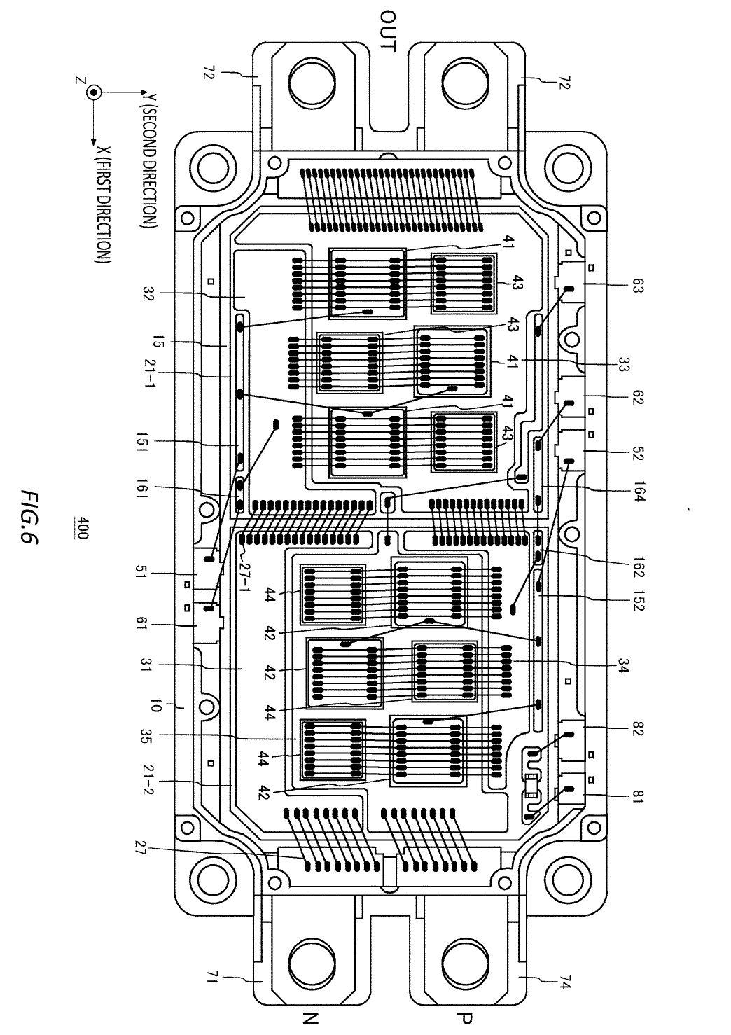

FIG. 6 shows a semiconductor module 400 in a modification example of the present invention. The semiconductor module 400 has an arrangement of the second gate pattern 152 and the second sense pattern 162, which is different from that of the semiconductor module 100 shown in FIG. 1. The second sense terminal portion 62 and the second gate terminal portion 52 may be aligned in the first direction. The third wiring pattern 33 and the fourth wiring pattern 34 may be aligned in the first direction.

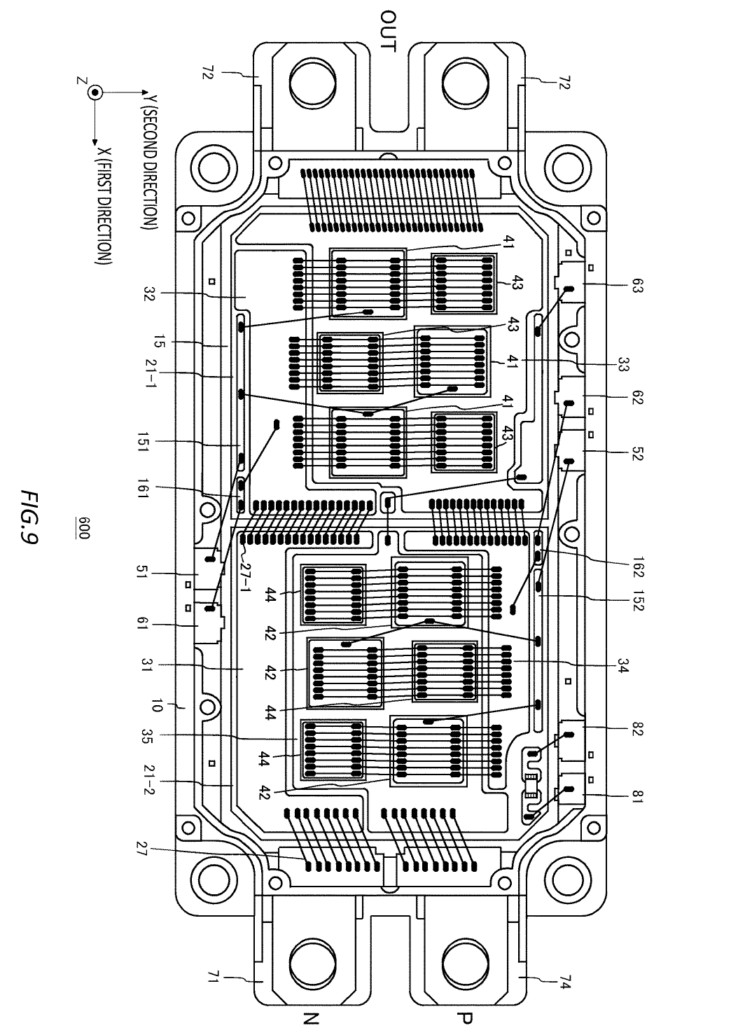

The second sense pattern 162 may be electrically connected between the fourth wiring pattern 34 and the second sense terminal portion 62. The second sense pattern 162 of the present example is connected to the fourth wiring pattern 34 using the point-to-point construction 27. The second sense pattern 162 of the present example is indirectly connected to the second sense terminal portion 62 via the fourth sense pattern 164. In another example described below (FIG. 9, 10, and the like), the second sense pattern 162 is connected to the second sense terminal portion 62 using the point-to-point construction 27.

The second sense pattern 162 may be separated from the fourth wiring pattern 34. In this way, as described above, the point-to-point construction 27 extending from the second sense terminal portion 62 can be connected near the center of the fourth wiring pattern 34.

The second gate pattern 152 may be connected to the second gate terminal portion 52 using the point-to-point construction 27. The semiconductor module 400 of the present example does not have the fourth gate pattern 154. That is, another pattern relaying the second gate pattern 152 and the second gate terminal portion 52 does not exist. In this way, the length of the third wiring pattern 33 in the second direction can be increased.

The second sense pattern 162 and the second gate pattern 152 may be aligned in the first direction. In other words, the second sense pattern 162 and the second gate pattern 152 of the present example at least partially overlap in the first direction. In this way, the width of the fourth wiring pattern 34 in the second direction can be increased, and the number of the point-to-point construction 27 connecting the third wiring pattern 33 and the fourth wiring pattern 34 can be increased. In this way, the current duty per one point-to-point construction 27 can be reduced, and the temperature rise in the point-to-point construction 27 can be suppressed. Therefore, the reliability of the semiconductor module 100 is improved. 80% or more of the second sense pattern 162 in the second direction and 80% or more of the second gate pattern 152 in the second direction may be aligned in the first direction. The above ratio may be 90% or more, or may be 100% or more.

Each of the second sense pattern 162 and the second gate pattern 152 may be aligned with the fourth wiring pattern 34 in the second direction. The entire second sense pattern 162 in the first direction may be aligned with the fourth wiring pattern 34 in the second direction. The entire second gate pattern 152 in the first direction may be aligned with the fourth wiring pattern 34 in the second direction.

The second sense terminal portion 62 and the second gate terminal portion 52 may be arranged at a predetermined position determined by a product standard. Each of the second sense terminal portion 62 and the second gate terminal portion 52 of the present example is aligned with the third wiring pattern 33 in the second direction. The entire second sense terminal portion 62 in the first direction may be aligned with the third wiring pattern 33 in the second direction. The entire second gate terminal portion 52 in the first direction may be aligned with the third wiring pattern 33 in the second direction. In the first direction, the distance between the second gate terminal portion 52 and the boundary between the third wiring pattern 33 and the fourth wiring pattern 34 may be greater than the distance between the first gate terminal portion 51 and the boundary between the first wiring pattern 31 and the second wiring pattern 32.

Each of the second sense pattern 162 and the second gate pattern 152 may have a longitudinal portion extending in the first direction. Each longitudinal portion may be aligned in the first direction. In this way, while the area on the second sense pattern 162 and the second gate pattern 152, which is occupied by the point-to-point construction 27 connecting therebetween, is secured, the number of the point-to-point construction 27 connecting the third wiring pattern 33 and the fourth wiring pattern 34 can be increased.

The second sense pattern 162 and the second gate pattern 152 may not be aligned with each other in the second direction. In other words, the second sense pattern 162 and the second gate pattern 152 may not have a portion overlapping each other in the second direction. In this way, the width of the fourth wiring pattern 34 in the second direction can be increased, and the number of the point-to-point construction 27 connecting the third wiring pattern 33 and the fourth wiring pattern 34 can be increased.

Neither the second sense pattern 162 nor the second gate pattern 152 may be aligned with the third wiring pattern 33 in the second direction. In other words, the second sense pattern 162 and the second gate pattern 152 may not have a portion overlapping with the third wiring pattern 33 in the second direction. In this way, the width of the third wiring pattern 33 in the second direction can be increased.

The point-to-point constructions 27 connecting the third wiring pattern 33 and the fourth wiring pattern 34 may be extended to have a gradient relative to the first direction and the second direction. The gradient may be a gradient in a top view. All of the point-to-point constructions 27 connecting the third wiring pattern 33 and the fourth wiring pattern 34 may be extended to have a gradient relative to the first direction and the second direction.

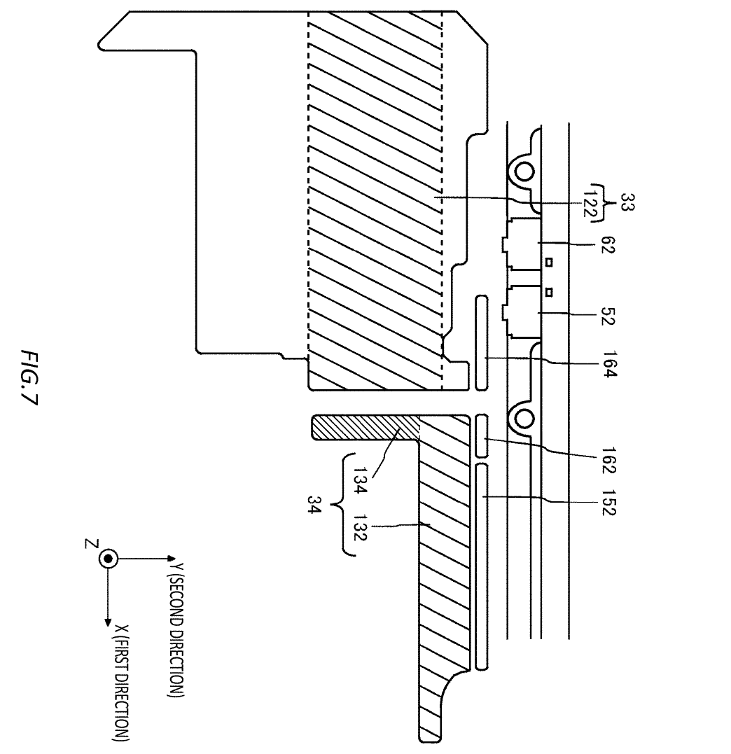

FIG. 7 is an enlarged drawing in the vicinity of a second wiring pattern 32 and a third wiring pattern 33 of the semiconductor module 400 shown in FIG. 6. In FIG. 7, the third wiring pattern 33, the fourth wiring pattern 34, the second gate terminal portion 52, the second sense terminal portion 62, the second gate pattern 152, the second sense pattern 162, and the fourth sense pattern 164 are shown, and the illustrations of another configuration such as the switching device or the point-to-point construction 27 are omitted.

The fourth wiring pattern 34 may have a fourth wide portion 132 and a fourth narrow portion 134. The fourth wide portion 132 may include a portion having the greatest length of the fourth wiring pattern 34 in the first direction. The fourth wide portion 132 may be a portion having a length of half or more of the longest length of the fourth wiring pattern 34 in the first direction. The fourth narrow portion 134 is a portion having a length smaller than that of the fourth wide portion 132 in the first direction. If there are a plurality of portions, each of which is equivalent to the portion, the fourth narrow portion 134 may be a portion that is the closest to the third wiring pattern 33. The length of the fourth narrow portion 134 in the first direction may be half or less, or may be one quarter or less of the length of the fourth wide portion 132 in the first direction. The fourth wide portion 132 and the fourth narrow portion 134 may not have a portion overlapping with each other in the first direction. In FIG. 7, the fourth wide portion 132 is roughly hatched, and the fourth narrow portion 134 is finely hatched.

A plurality of point-to-point constructions 27 may be connected to the fourth wide portion 132 (see FIG. 6). The connecting portion of the point-to-point construction 27 may be aligned in the second direction. The quantity of the point-to-point constructions 27 connected to the fourth wide portion 132 may be six or more. In the fourth wide portion 132, the connecting portions of six or more point-to-point constructions 27 may be aligned in a single line along the second direction. Since the current flowing in the fourth wiring pattern 34 is concentrated in the fourth wide portion 132, in this way, the current duty per one point-to-point construction 27 can be reduced.

The third wiring pattern 33 may have a third wide portion 122. The third wide portion 122 may include a portion in which the length of the third wiring pattern 33 in the first direction is the greatest, or may be a portion in which the length is the greatest. The third wide portion 122 may be a portion having a length of half or more of the longest length of the third wiring pattern 33 in the first direction. In FIG. 2, the third wide portion 122 is roughly hatched. A plurality of point-to-point constructions 27 may be connected to the third wide portion 122 (see FIG. 6). The connecting portion of the point-to-point construction 27 may be aligned in the second direction.

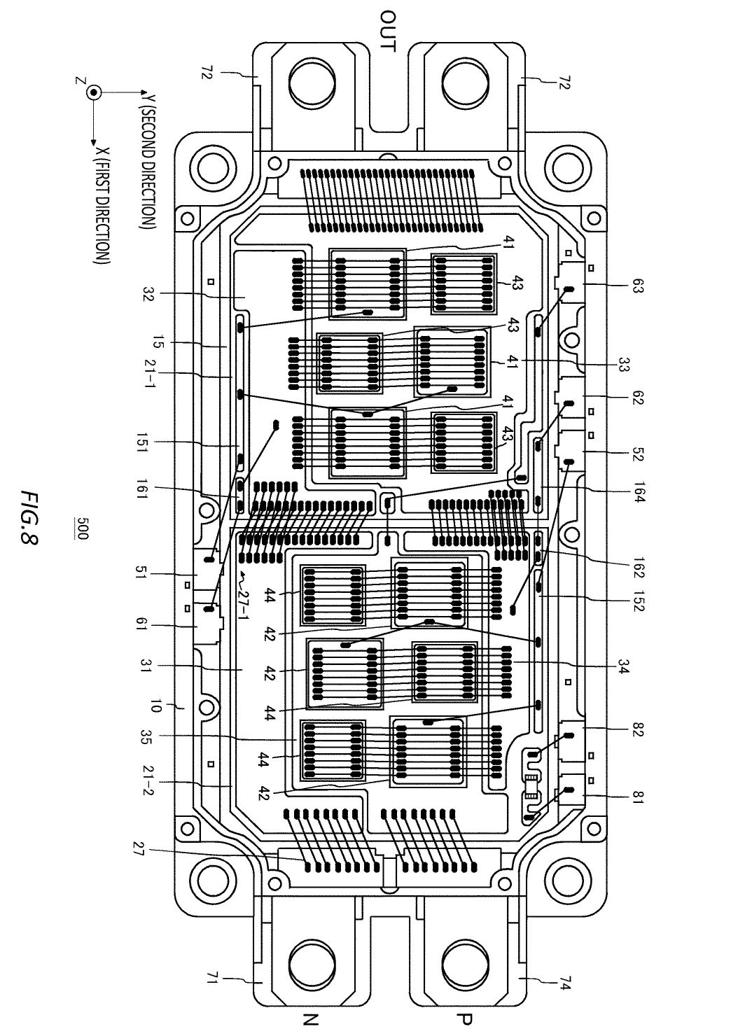

FIG. 8 shows a semiconductor module 500 in a modification example of the present invention. The semiconductor module 500 has a point-to-point construction 27 connecting a first wiring pattern 31 to a second wiring pattern 32, and a point-to-point construction 27 connecting a third wiring pattern 33 to a fourth wiring pattern 34, different from the semiconductor module 400 shown in FIG. 6.

In the first wide portion 102 (see FIG. 2) of the first wiring pattern 31, two or more connecting portions of the point-to-point construction 27 may be aligned in the first direction. In the first wide portion 102 of the present example, two connecting portions are aligned in the first direction. That is, the point-to-point constructions 27 connecting the first wiring pattern 31 and the second wiring pattern 32 of the present example are two-stepped. Twelve point-to-point constructions 27 are connected to the first wide portion 102 of the present example. In this way, the number of point-to-point constructions 27 connecting the first wiring pattern 31 and the second wiring pattern 32 can be further increased, and the current duty per one point-to-point construction 27 can be reduced. Also in the second wide portion 112 (see FIG. 2) of the second wiring pattern 32, two or more connecting portions of the point-to-point construction 27 may be aligned in the first direction. The point-to-point construction 27 shown in the present example may be applied to the semiconductor module of another example or the modification example.

In the fourth wide portion 132 (see FIG. 7) of the fourth wiring pattern 34, two or more connecting portions of the point-to-point construction 27 may be aligned in the first direction. In the fourth wide portion 132 of the present example, two connecting portions are aligned in the first direction. That is, the point-to-point constructions 27 connecting the third wiring pattern 33 and the fourth wiring pattern 34 of the present example are two-stepped. Eleven point-to-point constructions 27 are connected to the fourth wide portion 132 of the present example. In this way, the number of point-to-point constructions 27 connecting the third wiring pattern 33 and the fourth wiring pattern 34 can be further increased, and the current duty per one point-to-point construction 27 can be reduced. Also in the third wide portion 122 (see FIG. 7) of the third wiring pattern 33, two or more connecting portions of the point-to-point construction 27 may be aligned in the first direction. The point-to-point construction 27 shown in the present example may be applied to the semiconductor module of another example or the modification example.

FIG. 9 shows a semiconductor module 600 in a modification example of the present invention. The semiconductor module 600 has a connection between the second sense terminal portion 62 and the second sense pattern 162, which is different from that of the semiconductor module 400 shown in FIG. 6.

The second sense pattern 162 may be connected to the second sense terminal portion 62 using the point-to-point construction 27. The semiconductor module 600 of the present example does not have the fourth sense pattern 164. In this way, the length of the third wiring pattern 33 in the second direction can be increased.

Each of the second sense pattern 162 and the second gate pattern 152 may be aligned with the third wiring pattern 33 in the first direction. The entire second sense pattern 162 and second gate pattern 152 in the second direction may be aligned with the third wiring pattern 33 in the first direction. In this way, the length of the third wiring pattern 33 in the second direction can be increased.

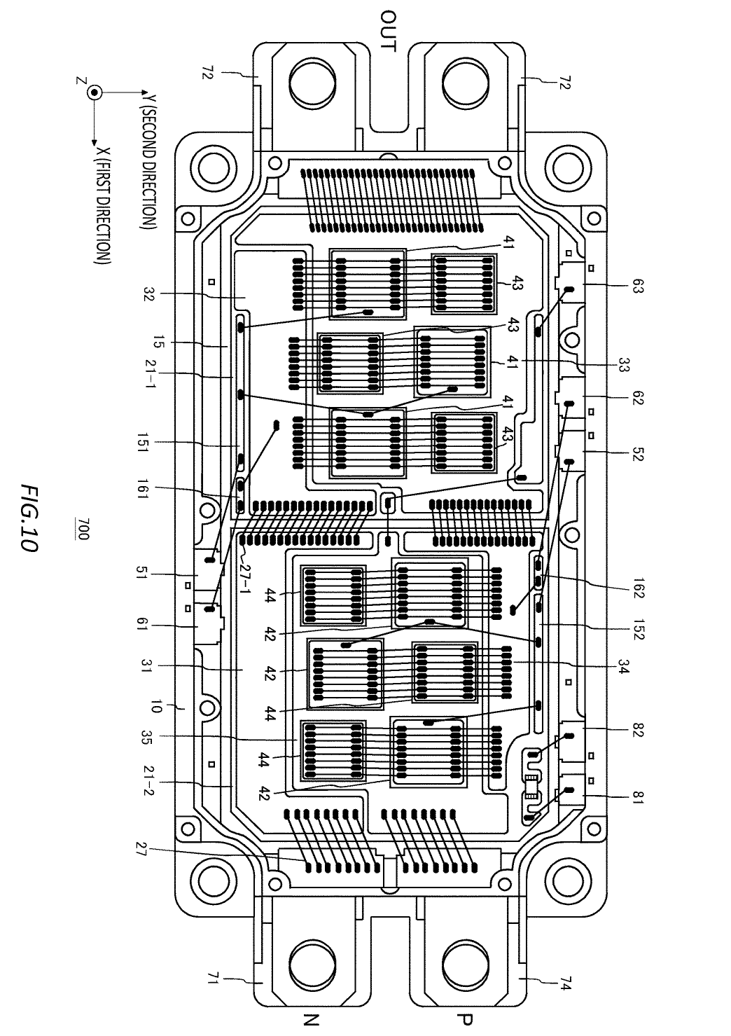

FIG. 10 shows a semiconductor module 700 in a modification example of the present invention. The semiconductor module 700 has an arrangement of the second sense pattern 162, the second gate pattern 152, and the fourth wiring pattern 34 different from that of the semiconductor module 600 shown in FIG. 9.

Also in the present example, the second sense pattern 162 may be connected to the second sense terminal portion 62 using the point-to-point construction 27. The semiconductor module 700 of the present example does not have the fourth sense pattern 164. In this way, the length of the third wiring pattern 33 in the second direction can be increased.

A part of the fourth wiring pattern 34 may be arranged between the second sense pattern 162 and the third wiring pattern 33 in the first direction. The point-to-point construction 27 may be connected to the part. In this way, the number of point-to-point constructions 27 connecting the third wiring pattern 33 and the fourth wiring pattern 34 can be further increased, and the current duty per one point-to-point construction 27 can be reduced. Similarly, also in the lower arm side, a part of the second wiring pattern 32 may be arranged between the first sense pattern 161 and the first wiring pattern 31 in the first direction. The point-to-point construction 27 may be connected to the part. In this way, the number of point-to-point constructions 27 connecting the first wiring pattern 31 and the second wiring pattern 32 can be further increased, and the current duty per one point-to-point construction 27 can be reduced. The arrangement on the second wiring pattern 32 may be applied to the semiconductor module in another example or the modification example.

While the present invention has been described above by way of the embodiments, the technical scope of the present invention is not limited to the scope described in the above-described embodiments. It is apparent to persons skilled in the art that various alterations and improvements can be added to the above-described embodiments. It is also apparent from the description of the claims that the embodiments to which such alterations or improvements are made can fall within the technical scope of the present invention.

What is claimed is:

1. A semiconductor module comprising a P terminal portion, an N terminal portion, and an OUT terminal portion, the semiconductor module comprising:
a first sense terminal portion and a first gate terminal portion arranged side by side in a first direction;
a first transistor chip that constitutes a lower arm and a second transistor chip that constitutes an upper arm, which are electrically connected in series between the P terminal portion and the N terminal portion, each having a connection node electrically connected to the OUT terminal portion;
a wiring substrate;
a first wiring pattern that is provided on the wiring substrate, and that is electrically connected between the first transistor chip and the N terminal portion;
a second wiring pattern that is provided on the wiring substrate, and that is electrically connected between the first transistor chip and the first wiring pattern;
a first sense pattern that is provided on the wiring substrate, that is electrically connected between the second wiring pattern and the first sense terminal portion, and that is separated from the second wiring pattern; and
a first gate pattern that is provided on the wiring substrate, and that is electrically connected between a gate pad of the first transistor chip and the first gate terminal portion; wherein
the first wiring pattern and the second wiring pattern are connected using a point-to-point construction,
the first sense pattern and the first sense terminal portion are connected using a point-to-point construction,
the first gate pattern and the first gate terminal portion are connected using a point-to-point construction, and
the first sense pattern and the first gate pattern are aligned in the first direction.

2. The semiconductor module according to claim 1, wherein each of the first sense pattern and the first gate pattern is aligned with the second wiring pattern in a second direction that is perpendicular to the first direction.

3. The semiconductor module according to claim 2, wherein each of the first sense terminal portion and the first gate terminal portion is aligned with the first wiring pattern in the second direction.

4. The semiconductor module according to claim 1, wherein each of the first sense pattern and the first gate pattern has a longitudinal portion extending in the first direction, and each of longitudinal portions, each of which is equivalent to the longitudinal portion, is aligned in the first direction.

5. The semiconductor module according to claim 1, wherein the first sense pattern and the first gate pattern are not aligned with each other in a second direction that is perpendicular to the first direction.

6. The semiconductor module according to claim 1, wherein each of the first sense pattern and the first gate pattern is aligned in the first wiring pattern in the first direction.

7. The semiconductor module according to claim 6, wherein neither the first sense pattern nor the first gate pattern is aligned with the first wiring pattern in a second direction that is perpendicular to the first direction.

8. The semiconductor module according to claim 6, wherein the point-to-point construction connected to the second wiring pattern is at least partially connected to a position in the first wiring pattern, the position overlapping both the first sense pattern and the first gate pattern in the first direction.

9. The semiconductor module according to claim 8, wherein the point-to-point construction extends to have a gradient relative to the first direction and a second direction that is perpendicular to the first direction.

10. The semiconductor module according to claim 6, wherein the first wiring pattern includes:
a first wide portion; and
a first narrow portion that has a width in the first direction smaller than that of the first wide portion, and
the first wide portion is aligned with each of the first sense pattern and the first gate pattern in the first direction.

11. The semiconductor module according to claim 6, wherein a first end side facing the second wiring pattern in the first wiring pattern extends closer to a side of the first gate terminal portion, in a second direction that is perpendicular to the first direction, than a second end side facing the first wiring pattern in the second wiring pattern.

12. The semiconductor module according to claim 1, wherein the first wiring pattern includes:
a first wide portion; and
a first narrow portion that has a width in the first direction smaller than that of the first wide portion, wherein
in the first wide portion, two or more connecting portions of the point-to-point construction are aligned in the first direction.

13. The semiconductor module according to claim 1, comprising:
a second sense terminal portion and a second gate terminal portion arranged side by side in the first direction;
a third wiring pattern that is provided on the wiring substrate, and that is electrically connected between the second transistor chip and the OUT terminal portion;
a fourth wiring pattern that is provided on the wiring substrate, and that is electrically connected between the second transistor chip and the third wiring pattern;
a second sense pattern that is provided on the wiring substrate, that is electrically connected between the fourth wiring pattern and the second sense terminal portion, and that is separated from the fourth wiring pattern; and
a second gate pattern that is provided on the wiring substrate, and that is electrically connected between a gate pad of the second transistor chip and the second gate terminal portion, wherein
the third wiring pattern and the fourth wiring pattern are connected using a point-to-point construction,
the second gate pattern and the second gate terminal portion are connected using a point-to-point construction, and
the second sense pattern and the second gate pattern are aligned in the first direction.

14. The semiconductor module according to claim 13, wherein each of the second sense pattern and the second gate pattern has a longitudinal portion extending in the first direction, and each of longitudinal portions, each of which is equivalent to the longitudinal portion, is aligned in the first direction.

15. The semiconductor module according to claim 13, wherein each of the second sense pattern and the second gate pattern is aligned with the fourth wiring pattern in a second direction that is perpendicular to the first direction.

16. The semiconductor module according to claim 15, wherein the second sense pattern and the second sense terminal portion are connected using a point-to-point construction.

17. The semiconductor module according to claim 16, wherein a part of the fourth wiring pattern is arranged between the second sense pattern and the third wiring pattern in the first direction.

18. The semiconductor module according to claim 13, wherein
the first sense pattern is electrically connected between the first transistor chip and the first sense terminal portion, and
the second sense pattern is electrically connected between the second transistor chip and the second sense terminal portion.

19. The semiconductor module according to claim 2, comprising:
a second sense terminal portion and a second gate terminal portion arranged side by side in the first direction;
a third wiring pattern that is provided on the wiring substrate, and that is electrically connected between the second transistor chip and the OUT terminal portion;
a fourth wiring pattern that is provided on the wiring substrate, and that is electrically connected between the second transistor chip and the third wiring pattern;
a second sense pattern that is provided on the wiring substrate, that is electrically connected between the fourth wiring pattern and the second sense terminal portion, and that is separated from the fourth wiring pattern; and
a second gate pattern that is provided on the wiring substrate, and that is electrically connected between a gate pad of the second transistor chip and the second gate terminal portion, wherein
the third wiring pattern and the fourth wiring pattern are connected using a point-to-point construction,
the second gate pattern and the second gate terminal portion are connected using a point-to-point construction, and
the second sense pattern and the second gate pattern are aligned in the first direction.

20. The semiconductor module according to claim 3, comprising:
a second sense terminal portion and a second gate terminal portion arranged side by side in the first direction;
a third wiring pattern that is provided on the wiring substrate, and that is electrically connected between the second transistor chip and the OUT terminal portion;
a fourth wiring pattern that is provided on the wiring substrate, and that is electrically connected between the second transistor chip and the third wiring pattern;
a second sense pattern that is provided on the wiring substrate, that is electrically connected between the fourth wiring pattern and the second sense terminal portion, and that is separated from the fourth wiring pattern; and
a second gate pattern that is provided on the wiring substrate, and that is electrically connected between a gate pad of the second transistor chip and the second gate terminal portion, wherein
the third wiring pattern and the fourth wiring pattern are connected using a point-to-point construction,
the second gate pattern and the second gate terminal portion are connected using a point-to-point construction, and
the second sense pattern and the second gate pattern are aligned in the first direction.
